(19) United States
(12) Patent Application Publication
(10) Pub. No.: US 2003/0183946 A1
(43) Pub. Date: Oct. 2, 2003

(54) Semiconductor device

(76) Inventors: Masatoshi Fukuda, Yokohama-shi (JP); Kaoru Kawai, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/397,517

(22) Filed: Mar. 27, 2003

(30) Foreign Application Priority Data
Mar. 28, 2002 (JP) 2002-090393
Mar. 19, 2003 (JP) 2003-075751

(51) Int. Cl. H01L 23/48; H01L 23/52; H01L 29/40

(52) U.S. Cl. 257/778

(57) ABSTRACT

Disclosed is a semiconductor device comprising a substrate, a first semiconductor chip having a thickness of 0.25 mm or less and mounted on the substrate through flip-chip connection with a gap of 0.055 mm or less, a conductive connector member connecting the chip to the substrate, and a molding resin layer covering the chip and formed of a cured resin comprising 75-92% by weight of an inorganic filler and 0.5-1.5% by weight of carbon black, a portion of the molding resin layer opposite to the substrate having a thickness of 0.15 mm or less, 99 wt % of the filler having longest diameter of 35 μm or less, the average longest diameter of the filler being 15 μm or less, and the content of fine filler having a longest diameter of 10 μm or less is within the range of 30-50% by weight based on the entire filler.

### CROSS-REFERENCE TO RELATED APPLICATIONS

This application is based upon and claims the benefit of priority from the prior Japanese Patent Applications No. 2002-090393, filed Mar. 28, 2002; and No. 2003-075751, filed Mar. 19, 2003, the entire contents of both of which are incorporated herein by reference.

### BACKGROUND OF THE INVENTION

1. Field of the Invention

This invention relates to a semiconductor device, in particular, to a semiconductor device wherein a semiconductor chip is encapsulated by using an encapsulating resin.

2. Description of the Related Art

In keeping with the technological development in recent years in the fields of semiconductor integrated circuits with respect to the enhancements in integration as well as in reliability of the semiconductor integrated circuits, efforts to further miniaturize and to make thinner semiconductor devices are now being made intensively. To meet such a trend, there is now an increasing demand for the development of an encapsulating resin excellent in properties.

In the QON (Quad Outline Nonleaded Package) of the conventional flip chip type, a semiconductor chip 4 is mounted via a conductive connector member 2 on the surface of a substrate 1 as shown in FIG. 1. The substrate 1 in this case is made of resin or ceramics, and provided on the surface thereof with a wiring circuit (not shown). The substrate 1 is also provided on the underside thereof with terminals 6 for external connection. The conductive connector member 2 is constituted by a bump 2a for the wiring circuit terminal of substrate 1 and a bump 2b for the semiconductor chip. These bumps are formed by gold or solder for instance.

An encapsulating resin layer 5 is disposed on the top surface and side faces of the semiconductor chip 4 as well as in a space or gap between the substrate 1 and the semiconductor chip 4. This encapsulating resin layer 5 can be formed by sealing en bloc the substrate 1 having the semiconductor chip 4 mounted thereon by a molding resin composition.

Since the space or gap between the substrate 1 and the semiconductor chip 4 is relatively small in height compared with the distance between a mold and the semiconductor chip 4, voids are more likely to be generated in the aforementioned space or gap on the occasion of sealing en bloc the substrate 1 by using a molding resin composition. In the meantime, the technique to make the body of a semiconductor device thinner has been further advanced in recent years, so that the thickness of the encapsulating resin layer 5 is inevitably made thinner. Therefore, there has been raised a problem that it is difficult to perfectly dispose a molding resin composition on the top surface of the semiconductor chip 4 and to fill the aforementioned space or gap with a molding resin composition in the process of performing the encapsulation of a semiconductor device by using a molding resin composition, thus increasing the possibility of generating voids therein.

In particular, if voids exist in a space between the substrate 1 and the semiconductor chip 4, the semiconductor chip 4 would be subjected to the pressure employed on the occasion of filling the space with a molding resin composition. As a result, a central portion of the semiconductor chip 4 would be pushed downward, thus giving rise to the generation of cracks of the semiconductor chip 4. The resin layer is peel off from the voids and cracks are generate, thereby the longtime reliability of the semiconductor device deteriorates.

It may be possible to suppress the generation of voids by increasing the pressure and temperature on the occasion of filling the space with a molding resin composition. However, the semiconductor chip may be caused to flow away by the pressure employed in this filling, or may be molten away by a high temperature.

These problems become causes for considerably degrading the reliability of a semiconductor device.

### BRIEF SUMMARY OF THE INVENTION

A semiconductor device according to one embodiment of the present invention comprises:

a substrate;

a first semiconductor chip mounted on the substrate through flip chip connection, the first semiconductor chip being spaced away from the substrate by a distance of 0.055 mm or less, the first semiconductor chip having a thickness of 0.25 mm or less;

a conductive connector member electrically connecting the first semiconductor chip to the substrate; and

a molding resin layer disposed over the substrate to cover the first semiconductor chip, and formed of a cured resin composition comprising 75-92% by weight of an inorganic filler and 0.5-1.5% by weight of carbon black, a portion of the molding resin layer opposite to the substrate having a thickness of 0.15 mm or less, 99% by weight of the inorganic filler having the longest diameter of 35 Um or less, the average longest diameter of the inorganic filler being 15 μm or less, and the content of fine filler having a longest diameter of 10 μm or less being confined within the range of 30 to 50% by weight based on the entire weight of the inorganic filler.

A semiconductor device according to another embodiment of the present invention comprises:

a substrate;

a first semiconductor chip mounted on the substrate;

a first wire having a diameter of 28 μm or less and electrically connecting the first semiconductor chip to the substrate; and

a molding resin layer disposed over the substrate to cover the first semiconductor chip, and formed of a cured resin composition comprising 75-92% by weight of an inorganic filler and 0.5-1.5% by weight of carbon black, a portion of the molding resin layer opposite to the substrate having a thickness of 0.2 mm or less, 99% by weight of the inorganic filler having the longest diameter of 35 μm or less, the average longest diameter of the inorganic filler being 15 μm or less, and the content of fine filler having a longest diameter of 10 μm or less being confined within the range of 30 to 50% by weight based on the entire weight of the inorganic filler.

### BRIEF DESCRIPTION OF THE SEVERAL VIEWS OF THE DRAWING

FIG. 1 is a cross-sectional view illustrating a semiconductor device according to the prior art;

FIG. 2 is a cross-sectional view illustrating a semiconductor device according to one embodiment of the present invention;

FIG. 3 is a cross-sectional view illustrating a semiconductor device according to another embodiment of the present invention;

FIG. 4 is a cross-sectional view illustrating a semiconductor device according to another embodiment of the present invention;

FIG. 5 is a cross-sectional view illustrating a semiconductor device according to another embodiment of the present invention;

FIG. 6 is a cross-sectional view illustrating a semiconductor device according to another embodiment of the present invention;

FIG. 7 is a cross-sectional view illustrating a semiconductor device according to another embodiment of the present invention; and

FIG. 8 is a cross-sectional view illustrating a semiconductor device according to another embodiment of the present invention.

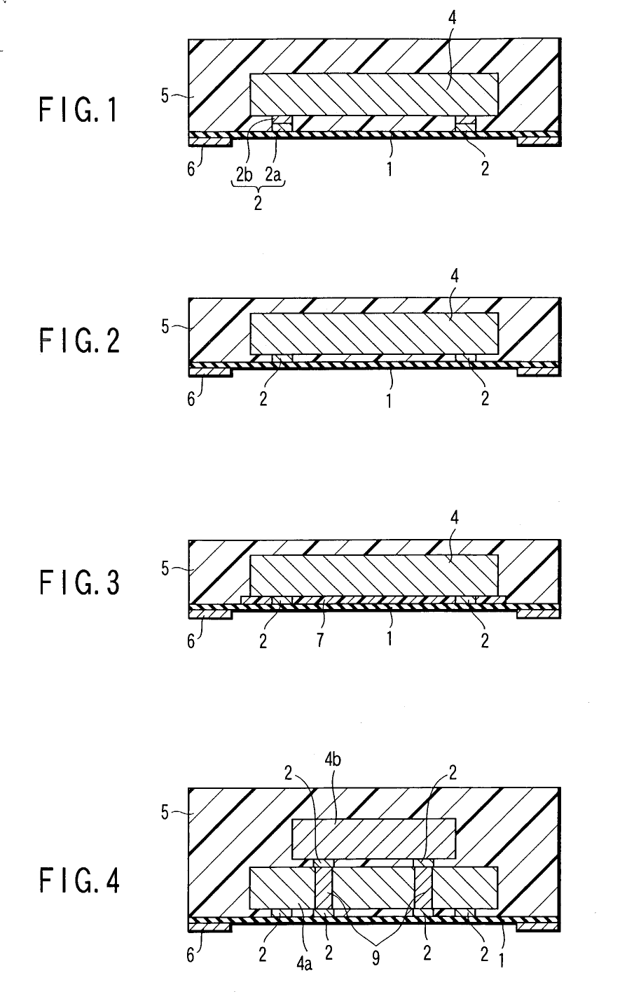

### DETAILED DESCRIPTION OF THE INVENTION

The embodiments according to the present invention will be explained in detail in reference to the drawings as follows.

FIG. 2 is a cross-sectional view illustrating a semiconductor device according to one embodiment of the present invention.

In this semiconductor device shown herein, a semiconductor chip 4 is mounted via a conductive connector member 2 on the surface of a substrate 1. The substrate 1 may be formed of a polyimide tape or ceramics, and provided on the underside thereof with terminals 6 for external connection.

Although not shown in the drawing, the conductive connector member 2 is constituted by a bump for the semiconductor chip 4 and a bump for the wiring circuit terminal of substrate 1. These bumps may be formed by tin/silver solder, gold, tin/lead solder, tin, tin/silver/copper solder, tin/zinc solder, tin/bismuth solder or nickel, for instance. The terminals 6 for external connection may be formed by tin/silver solder, tin/lead solder or tin, for instance.

An encapsulating resin layer 5 is disposed on the top surface and side faces of the semiconductor chip 4, on the top surface of the substrate 1 as well as in a space between the substrate 1 and the semiconductor chip 4.

In this semiconductor device shown in FIG. 2, the height of the space between the substrate 1 and the semiconductor chip 4 is 0.055 mm or less, and the thickness of the semiconductor chip 4 is 0.25 mm or less. Further, the thickness of the portion of encapsulating resin layer 5 opposite to the substrate is 0.15 mm or less. In this case, the thickness of the portion of encapsulating resin layer 5 disposed over the semiconductor chip 4 is 0.15 mm or less. These dimensions are confined as mentioned above in order to minimize the thickness as a whole of the semiconductor device.

An overall height of the semiconductor device (a distance as measured from the terminal 6 for external connection to the top surface of the molding resin layer 5) should preferably be 0.500 mm or less. Further, the portion of the encapsulating resin layer 5 disposed over the semiconductor chip 4 should preferably be confined to a thickness not more than three times the height of the space.

In order to form a molding resin layer while preventing voids from being generated in a narrow space as small as 0.055 mm or less, it is required to employ a molding resin composition excellent in fluidity and moldability. Therefore, with a view to obtaining optimum molding resin compositions, various studies have been made by the present inventors.

The molding resin composition comprises an inorganic filler, epoxy resin, phenolic resin, a cure promoting agent and carbon black.

As for epoxy resin, there is not any particular limitation and hence it may be selected from those having two or more epoxy groups per molecule. Specific examples of this epoxy resin include, for example, orthocresol novolac type epoxy resin, dicyclopentadiene-modified epoxy resin, triphenol methane type epoxy resin, bipheyl type epoxy resin and epi-bis type epoxy resin. These epoxy resins may be employed singly or in combination.

As for phenolic resin, there is not any particular limitation as long as it is provided with two or more phenolic hydroxyl groups capable of reacting with the epoxy group of epoxy resin. Specific examples of this phenolic resin include, for example, phenol novolac resin, phenol aralkyl resin, naphthol aralkyl resin and dicyclopentadiene-modified phenol resin. These epoxy resins may be employed singly or in combination.

As for the cure promoting agent, various kinds of cure promoting agent such as a phosphoric cure promoting agent, an imidazolic cure promoting agent, a DBU type cure promoting agent, etc., may be employed. These cure promoting agents may be employed singly or in combination. The mixing ratio of these cure promoting agents should preferably be within the range of 0.01 to 5% by weight based on the entire weight of the resin composition. If this mixing ratio is less than 0.01% by weight, the gelling time of the resin composition may be prolonged and at the same time, the curing property of the resin composition may deteriorate. On the other hand, if this mixing ratio exceeds 5% by weight, the fluidity of the resin composition will deteriorate extremely, thus possibly inviting the deterioration in electrical properties as well as in humidity resistance of the molding resin layer.

Carbon black is incorporated herein for the purpose of preventing the malfunction of the semiconductor chip that may be caused by the transmission of light, so that carbon black may be of any kind which is generally employed as a sealing or encapsulating material.

The fluidity of the molding resin composition is highly dependent on the kind of inorganic filler to be incorporated. For the purpose of comparison, eight kinds of molding resin compositions as shown in the following Table 1 were prepared by using different kinds of fused silica as an inorganic filler.

Then, a semiconductor device as shown in FIG. 2 was manufactured by using each of these molding resin compositions. In this case, the filling properties of these molding resin compositions into the space between the substrate 1 and the semiconductor chip 4 were investigated. In this assessment, the molding resin compositions in which no voids generate in the space were indicated as being “O”, while the molding resin compositions in which voids generate in the space were indicated as being “X”.

Incidentally, at least 30 samples were investigated and the void is defined as one having 0.020 mm or more in the longer diameter.

TABLE 1

| | | Longest | Average | | |
|---|---|---|---|---|---|
| Resin | Configu- | Dia. | Dia. | Cont. | Filling |
| No. | ration | (μm) | (μm) | (wt %) | property |
| 1 | Crushed | 105 | 30 | 86 | X |
| 2 | Spherical | 75 | 16 | 86 | X |
| 3 | Spherical | 75 | 9 | 86 | X |
| 4 | Spherical | 75 | 6 | 86 | X |
| 5 | Spherical | 75 | 6 | 82 | X |
| 6 | Spherical | 35 | 9 | 86 | O |
| 7 | Spherical | 35 | 6 | 86 | O |
| 8 | Spherical | 35 | 6 | 82 | O |

The longest diameter is meant to indicate the length of the longest portion of the particle of inorganic filler, and the average diameter is meant to indicate the average value of the longest diameters of the fuller particles.

AS shown in Table 1, the molding resin compositions identified by Resin Nos. 6, 7 and 8 were excellent in filling properties. Therefore, the inorganic filler useful in the embodiment of the present invention was defined as having a longest diameter of 35 μm or less and an average diameter of 15 μm or less. Incidentally, in the embodiments of the present invention, 99% by weight or more of the particles of inorganic filler are required to satisfy the aforementioned conditions regarding the longest diameter. It is more desirable that the content of the particles of inorganic filler which satisfy the aforementioned conditions is 99.9% by weight or more, most preferably 99.99% by weight or more.

In the fused silica employed in these resin Nos. 6, 7 and 8, the ratio of fine filler having a longest diameter of 10 μm or less was confined within the range of 30 to 50% by weight based on the entire weight of the fused silica.

Further, it was found that when the content of the inorganic filler was less than 75% by weight, the reflow resistance and packaging reliability of a semiconductor device deteriorated. On the other hand, the upper limit of the content of the inorganic filler was found limited to 92% by weight for the convenience of manufacturing the molding resin.

Based on the aforementioned considerations, the inorganic filler to be incorporated into the molding resin composition employed in the embodiments of the present invention is confined to have the following features:

(1) The longest diameter thereof is 35 μm or less;

(2) The average diameter thereof is 15 μm or less;

(3) The content of fine filler having the longest diameter of 10 μm or less is confined within the range of 30 to 50% by weight; and

(4) The content of the inorganic filler is confined within the range of 75 to 92% by weight.

In the foregoing explanations, fused silica is described as an example of the inorganic filler. However, as long as the aforementioned conditions are met, it is also possible to employ crushed silica, etc.

The molding resin composition wherein the features of the inorganic filler to be included therein are defined as described above is excellent in fluidity as well as in moldability. Therefore, the molding resin composition defined above can be easily introduced into a narrow space on the occasion of performing the aforementioned en bloc resin encapsulation, thereby making it possible to suppress the generation of voids. Furthermore, since the generation of voids can be suppressed in this manner, the generation of cracks in a chip due to the pressure to be applied on the occasion of filling the narrow space with the molding resin composition is prevented, thus making it possible to enhance the reliability of a semiconductor device to be manufactured. Moreover, it is now possible to manufacture a semiconductor device minimized in thickness. The peeling of the resin layer does not generate, thereby the longtime reliability of the semiconductor device is improved.

Additionally, since the molding resin composition defined above is excellent in fluidity, it is no longer required to increase the filling pressure of the resin composition on the occasion of the encapsulation of the semiconductor device. Therefore, the semiconductor device will not flow away by the pressure employed in resin filling.

Further, in the embodiments of the present invention, the content of carbon black to be incorporated into the molding resin composition is confined within the range of 0.5 to 1.5% by weight.

This range in content of carbon black was determined as follows. First of all, several kinds of molding resin compositions were prepared by varying the content of carbon black. Then, a semiconductor device was manufactured by using each of these molding resin compositions, and the light transmittance of the resultant semiconductor device was measured. In this case, the overall height of the semiconductor device was set to 0.450 mm and the wavelength of light was confined within the range of 1000 to 2000 nm.

As a result, the light transmittance of the semiconductor device encapsulated by using a molding resin containing 0.50% by weight or more of carbon black was found to be 0.20% or less. Incidentally, it was confirmed that as long as the light transmittance of the semiconductor device was limited to 0.20% or less, it was possible to substantially prevent the generation of malfunction of the semiconductor chip. Moreover, it was also possible to keep the volume resistivity of the molding resin composition at 10⁸ Ω·cm or more at room temperature.

On the other hand, if the content of carbon black exceeds 1.5% by weight, the volume resistivity of the molding resin composition deteriorates, thus causing the generation of a malfunction of the semiconductor device to be manufactured. Therefore, the upper limit in content of carbon black should be limited to 1.5% by weight.

The content of carbon black is confined within the range of 0.50 to 1.5% by weight in order to suppress light transmittance and to prevent the generation of a malfunction of the semiconductor chip even in the case where the resin encapsulation is performed relatively thin.

Since the inorganic filler and carbon black are included in the molding resin composition in such a manner as defined above, the semiconductor device according to the embodiments of the present invention is excellent in reliability and, at the same time, malfunction due to the transmittance of light can be prevented.

Namely, the molding resin layer in the semiconductor device according to the embodiments of the present invention is formed by the curing of a molding resin composition comprising 75-92% by weight of an inorganic filler and 0.5-1.5% by weight of carbon black. In particular, 99% by weight of the inorganic filler have a longest diameter of 35 μm or less, the average longest diameter of the inorganic filler is 15 μm or less, and the content of fine filler having a longest diameter of 10 μm or less is confined within the range of 30 to 50% by weight based on the entire weight of said inorganic filler.

The semiconductor device shown in FIG. 2 can be variously modified.

For example, as shown in FIG. 3, an adhesive layer 7 may be interposed between the substrate 1 and the semiconductor chip 4. This adhesive layer 7 interposed between the substrate 1 and the semiconductor chip 4 acts to alleviate internal stress. Therefore, the provision of the adhesive layer is especially effective in the case where the size of the semiconductor device is relatively large, for example, 7 mm square or more, or the size of the semiconductor chip 4 is relatively large, for example, 6 mm square or more.

Further, as shown in FIG. 4, a second semiconductor chip 4b may be laminated on the first semiconductor chip 4a. This second semiconductor chip 4b is connected, via a through-conductive portion 9 formed penetrating the first semiconductor chip 4a and the conductive connector member 2, to the substrate 1.

This second semiconductor chip 4b may be connected, via a wire, to the substrate 1 as shown in FIG. 5. In the semiconductor device shown in FIG. 5, this second semiconductor chip 4b is disposed on the first semiconductor chip 4a with an adhesive layer 7b being interposed therebetween, and is connected by a second wire 8b to the substrate 1. This second wire 8b may be formed of a gold wire having a diameter of about 28 μm.

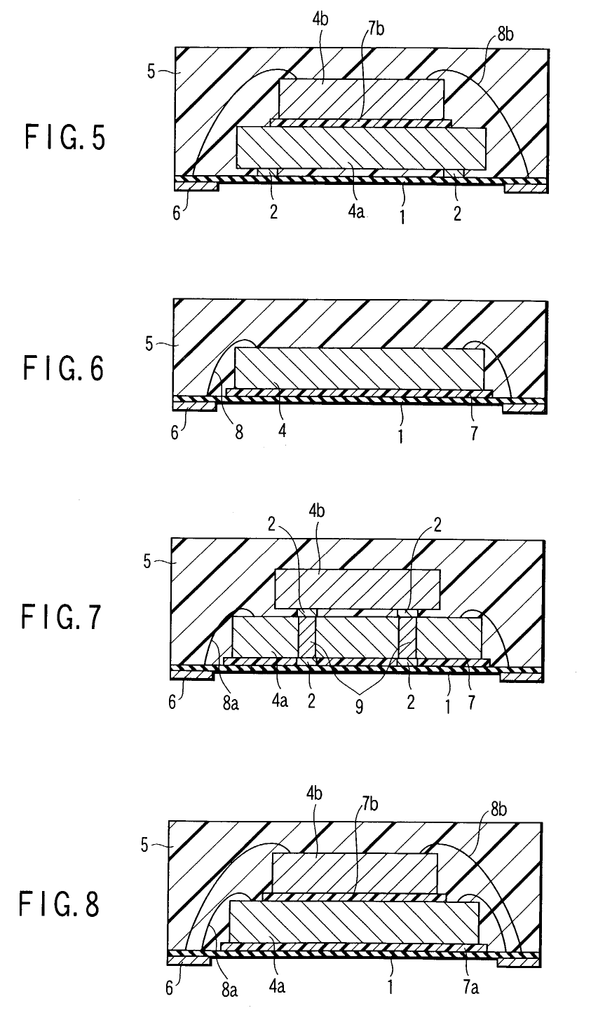

FIG. 6 is a cross-sectional view illustrating a semiconductor device according to another embodiment of the present invention.

In the semiconductor device shown in FIG. 6, the semiconductor chip 4 is mounted through an adhesive layer 7 on the substrate 1. This semiconductor chip 4 is electrically connected to a terminal of the wiring circuit (not shown) of the substrate by using a gold wire 8 having a diameter of 28 μm or less. As for the material of the substrate 1, it is possible to employ the same materials explained above.

The molding resin layer 5 is disposed on the top surface and side faces of the semiconductor chip 4 and on the top surface of the substrate 1. This molding resin layer 5 can be formed by curing a molding resin composition formulated to satisfy the conditions already discussed above with respect to the inorganic material and carbon black.

In the semiconductor device shown in FIG. 6, in order to minimize the overall thickness of the semiconductor device, the thickness of the portion of molding resin layer 5 opposite to the substrate 1 is confined to 0.2 mm or less. In this case, the thickness of the portion of molding resin layer 5 disposed over the semiconductor chip 4 is confined to 0.2 mm or less.

In the case of the conventional semiconductor device where a semiconductor chip is connected through a wire with the substrate, the wire may be deformed during the process of encapsulation by the effect of the shearing force caused by the molding resin composition. In that case, wires may contact each other, thus giving rise to the generation of electrical malfunction of the semiconductor device.

Whereas, in the case of the semiconductor device shown in FIG. 6, the semiconductor device is encapsulated by using a molding resin composition excellent in fluidity and moldability, it is possible to prevent the wire from being deformed.

The semiconductor device shown in FIG. 6 may be constructed as a 2-ply laminate structure as shown in FIGS. 4 and 5. FIGS. 7 and 8 illustrate this modified example.

The semiconductor device shown in FIG. 7 is constructed in the same manner as the semiconductor device shown in FIG. 4 except that the first semiconductor chip 4a is connected via a wire 8a to the substrate 1. The semiconductor device shown in FIG. 8 is constructed also in the same manner as the semiconductor device shown in FIG. 5 except that the first semiconductor chip 4a is connected via a wire 8a to the substrate 1. As shown in FIGS. 5 and 8, a second wire 8b disposed so as to connect the second semiconductor chip 4b to the substrate 1 is longer than the first wire 8a. Since a molding resin composition excellent in fluidity is employed in the embodiments of the present invention, even this long wire can be prevented from being deformed.

Incidentally, it is also possible to laminate a third semiconductor chip on the second semiconductor chip 4b to make them into a 3-ply laminate structure.

The present invention can be variously modified within the spirit thereof.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a substrate;
a first semiconductor chip mounted on said substrate through flip chip connection, said first semiconductor chip being spaced away from said substrate by a distance of 0.055 mm or less, said first semiconductor chip having a thickness of 0.25 mm or less;
a conductive connector member electrically connecting said first semiconductor chip to said substrate; and
a molding resin layer disposed over said substrate to cover said first semiconductor chip, and formed of a cured resin composition comprising 75-92% by weight of an inorganic filler and 0.5-1.5% by weight of carbon black, a portion of said molding resin layer opposite to said substrate having a thickness of 0.15 mm or less, 99% by weight of said inorganic filler having the longest diameter of 35 μm or less, the average longest diameter of said inorganic filler being 15 μm or less, and the content of fine filler having a longest diameter of 10 μm or less being confined within the range of 30 to 50% by weight based on the entire weight of said inorganic filler.

2. The semiconductor device according to claim 1, further comprising a molding resin layer interposed between said substrate and said first semiconductor chip, and formed of a cured resin composition comprising 75-92% by weight of an inorganic filler and 0.5-1.5% by weight of carbon black, 99% by weight of said inorganic filler having the longest diameter of 35 μm or less, the average longest diameter of said inorganic filler being 15 μm or less, and the content of fine filler having a longest diameter of 10 μm or less being confined within the range of 30 to 50% by weight based on the entire weight of said inorganic filler.

3. The semiconductor device according to claim 1, further comprising an adhesive layer interposed between said substrate and said first semiconductor chip.

4. The semiconductor device according to claim 1, wherein the portion of said molding resin layer disposed over said first semiconductor chip has a thickness not more than three times larger than the distance between said substrate and said first semiconductor chip.

5. The semiconductor device according to claim 1, wherein said conductive connector member is formed of a material comprising tin/silver solder.

6. The semiconductor device according to claim 1, wherein said conductive connector member is formed of a material comprising gold.

7. The semiconductor device according to claim 1, wherein said conductive connector member is formed of a material comprising tin/lead solder.

8. The semiconductor device according to claim 1, wherein said conductive connector member is formed of a material comprising tin, tin/silver/copper solder, tin/zinc solder, tin/bismuth solder or nickel.

9. The semiconductor device according to claim 1, further comprising a second semiconductor chip disposed on said first semiconductor chip, said second semiconductor chip being electrically connected to said substrate, and being covered together with said first semiconductor chip by said molding resin.

10. The semiconductor device according to claim 9, wherein said second semiconductor chip is electrically connected, through a bump, to said substrate.

11. The semiconductor device according to claim 9, wherein said second semiconductor chip is electrically connected, through a wire, to said substrate.

12. The semiconductor device according to claim 11, wherein said wire is formed of a material comprising gold.

13. The semiconductor device according to claim 12, wherein said wire has a diameter of 28 μm.

14. A semiconductor device comprising:
a substrate;
a first semiconductor chip mounted on said substrate;
a first wire having a diameter of 28 μm or less and electrically connecting said first semiconductor chip to said substrate; and
a molding resin layer disposed over said substrate to cover said first semiconductor chip, and formed of a cured resin composition comprising 75-92% by weight of an inorganic filler and 0.5-1.5% by weight of carbon black, a portion of said molding resin layer opposite to said substrate having a thickness of 0.2 mm or less, 99% by weight of said inorganic filler having the longest diameter of 35 μm or less, the average longest diameter of said inorganic filler being 15 μm or less, and the content of fine filler having a longest diameter of 10 μm or less being confined within the range of 30 to 50% by weight based on the entire weight of said inorganic filler.

15. The semiconductor device according to claim 14, further comprising an adhesive layer interposed between said substrate and said first semiconductor chip.

16. The semiconductor device according to claim 14, further comprising a second semiconductor chip disposed on said first semiconductor chip, said second semiconductor chip being electrically connected to said substrate, and being covered together with said first semiconductor chip by said molding resin.

17. The semiconductor device according-to claim 16, wherein said second semiconductor chip is electrically connected, through a bump, to said substrate.

18. The semiconductor device according to claim 16, wherein said second semiconductor chip is electrically connected, through a second wire, to said substrate.

19. The semiconductor device according to claim 18, wherein said second wire is formed of a material comprising gold.

20. The semiconductor device according to claim 19, wherein said second wire has a diameter of 28 μm.
